(19) United States
(12) Patent Application Publication
(10) Pub. No.: US 2005/0204214 A1
(43) Pub. Date: Sep. 15, 2005

(54) Distributed montoring in a telecommunications system

(75) Inventor: David Arthur Welch, Sugar Grove, IL (US)

Correspondence Address: DUFT BORNSEN & FISHMAN, LLP, 1526 SPRUCE STREET, SUITE 320, BOULDER, CO, 80302, US

(73) Assignee: Lucent Technologies Inc., Murray Hill, NJ (US)

(21) Appl. No.: 10/785,434

(22) Filed: Feb. 24, 2004

(51) Int. Cl. G11B 5/00; G11B 20/20; G06K 5/04; G06F 11/00; G01R 31/28

(52) U.S. Cl. 714/712

(57) ABSTRACT

A telecommunication system and method are disclosed. The telecommunication network is comprised of a plurality of peer communication devices coupled to a control system. Each of the communication devices collects performance data on its own performance and transfers the performance data to the control system. The control system, in response to receiving the performance data, processes the performance data from the communication devices to generate a performance file that indicates the performance of each of the communication devices. The control system transfers the performance file to each of the communication devices. Responsive to receiving the performance file, each of the communication devices processes the performance file to compare its performance to the performance of the other peer communication devices. Each of the communication devices may process the performance file to improve its performance.

### BACKGROUND OF THE INVENTION

1. Field of the Invention

The invention is related to the field of communications, and in particular, to system monitoring that is distributed among peer communication devices of a telecommunications system.

2. Statement of the Problem

Communication providers monitor communication systems for faults, failures or malfunctions of resources, errors in data, etc (herein referred to as faults). One reason may be that the communication provider strives to operate systems at a particular reliability level (i.e., the percent of time the systems will be available for providing usable service). Another reason may be that, if the communication provider guarantees a particular Quality of Service (QoS), then the provider may want to monitor systems to ensure that the agreed-to QoS is provided to the customers. If a fault is detected in the system, then the communication provider can take the appropriate recovery actions to address the fault.

Traditionally, the communication providers monitor the communication systems and provide recovery actions using a centralized system monitor. The centralized system monitor is generally comprised of hardware and software that monitors the communication system by receiving reports of faults from lower-level devices. The system monitor processes the fault reports from the lower-level devices to determine if any recovery actions should be taken.

The lower-level devices are not currently active participants in monitoring the communication system and providing recovery actions. The lower-level devices may be able to handle simple faults locally, but for the most part, the lower-level devices just report the faults to the system monitor and rely on the system monitor to decide what recovery actions to take.

As an example, assume that a first lower-level device is called “processing unit A” and a second lower-level device is called “processing unit B”, and that processing unit A is transferring data to processing unit B. Also assume that there is a fault in the hardware or software of processing unit A and that the data being transferred to processing unit B is faulty. Processing unit B receives the data from processing unit A and detects errors in the data (i.e., parity errors or check-sum errors). Responsive to detecting the errors in the data, processing unit B may generate a fault report indicating the data errors, and transfer the fault report to the system monitor.

One problem with a centralized system monitor is that the system monitor may initiate incorrect recovery actions. Because processing unit B reported the fault to the system monitor, the system monitor may take processing unit B out of service or provide other recovery actions on processing unit B. Even though processing unit B may be healthy and the fault lies in processing unit A, the system monitor may unfortunately perform incorrect recovery actions on processing unit B based on the fault report from processing unit B. Taking incorrect actions such as this increases system downtime and decreases system availability.

Another problem with a centralized system monitor is that the system monitor may delay in initiating recovery actions. Before initiating recovery actions based on the fault report from processing unit B, the system monitor may wait for additional fault reports. By waiting for additional fault reports, the system monitor may avoid taking incorrect recovery actions. For instance, if the system monitor receives fault reports from other processing units communicating with processing unit A, then the system monitor may be able to determine that the fault lies in processing unit A instead of processing unit B. At times of low traffic, the system monitor may wait minutes or hours to receive the additional fault reports. Consequently, the system monitor may unfortunately delay in providing recovery actions to processing unit A. During the time processing unit A is unhealthy, processing unit A may be decreasing the reliability of the overall system.

### SUMMARY OF THE SOLUTION

The invention solves the above problems and other problems with telecommunications systems and methods of operating a telecommunication system in exemplary embodiments described herein. The telecommunication system embodying the invention includes distributed monitoring by having lower-level devices actively participate in monitoring the telecommunication system. The lower-level devices may also actively participate in initiating recovery actions locally. The lower-level devices do not necessarily have to rely on a centralized system monitor, as in the prior art, to monitor the telecommunication system and initiate recovery if necessary. Because more of the system monitoring is performed locally on a device, the device may advantageously avoid taking incorrect recovery actions or delaying the initiation of the recovery actions. This may improve system availability and reliability.

The telecommunication system embodying the invention is comprised of a plurality of peer communication devices coupled to a control system. The communication devices handle telecommunications data or are configured to handle telecommunications data. For instance, the communication devices may process, route, or otherwise handle packets of a voice or data call. While handling the telecommunications data, each of the communication devices collects performance data. An individual communication device collects performance data on its own performance. Each of the communication devices transfers the performance data to the control system. The control system, in response to receiving the performance data, processes the performance data from the communication devices to generate a performance file that indicates the performance of each of the communication devices. The performance file may include some or all of the performance data provided by each of the communication devices. The control system transfers the performance file to each of the communication devices. Responsive to receiving the performance file, each of the communication devices processes the performance file to compare its own performance to the performance of the other peer communication devices.

The invention may include other exemplary embodiments described below.

### DESCRIPTION OF THE DRAWINGS

The same reference number represents the same element on all drawings.

FIG. 1 illustrates a telecommunication system in an exemplary embodiment of the invention.

FIGS. 2A-2B are flow charts illustrating a method of operation of the telecommunication system of FIG. 1 in an exemplary embodiment of the invention.

FIG. 3 illustrates a wireless communication network in an exemplary embodiment of the invention.

FIG. 4 illustrates a Radio Network Controller (RNC) in an exemplary embodiment of the invention.

FIG. 5 illustrates a Packet Control Function (PCF) card in an exemplary embodiment of the invention.

### DETAILED DESCRIPTION OF THE INVENTION

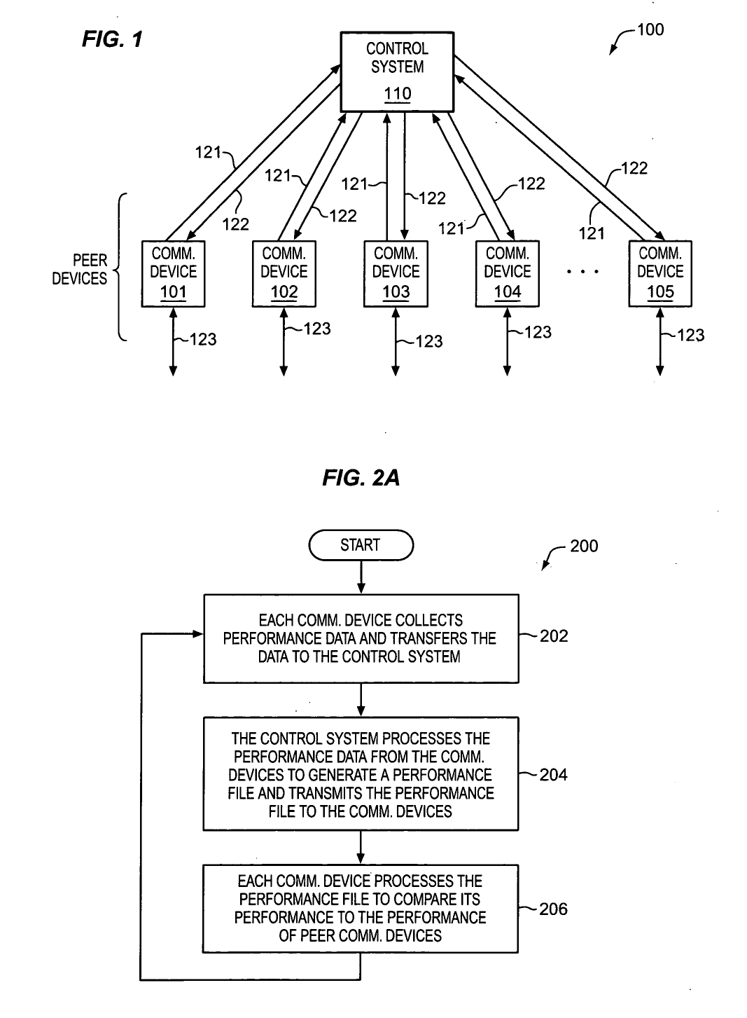

FIGS. 1, 2A-2B, and 3-5 and the following description depict specific exemplary embodiments of the invention to teach those skilled in the art how to make and use the best mode of the invention. For the purpose of teaching inventive principles, some conventional aspects of the invention have been simplified or omitted. Those skilled in the art will appreciate variations from these embodiments that fall within the scope of the invention. Those skilled in the art will appreciate that the features described below can be combined in various ways to form multiple variations of the invention. As a result, the invention is not limited to the specific embodiments described below, but only by the claims and their equivalents.

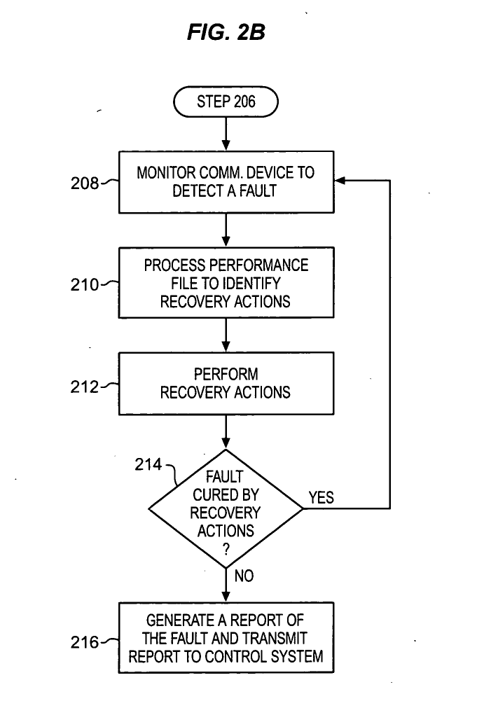

Telecommunication System Configuration and Operation—FIGS. 1, 2A-2B

FIG. 1 illustrates a telecommunication system 100 in an exemplary embodiment of the invention. Telecommunication system 100 comprises a plurality of communication devices 101-105 coupled to a control system 110. Communication devices 101-105 are peer devices. An example of a communication device 101-105 may be a communication card in a Radio Network Controller (RNC) of a Radio Access Network (RAN) re-configured or re-programmed to operate as described below. An example of a control system 110 may be a conventional system monitor re-configured or re-programmed to operate as described below. Telecommunication system 100 may include other components, devices, or systems not shown in FIG. 1.

FIG. 2A is a flow chart illustrating a method 200 of operation of telecommunication system 100 in an exemplary embodiment of the invention. Using method 200, telecommunication system 100 provides distributed monitoring. For understanding method 200, assume that communication devices 101-105 in FIG. 1 are handling telecommunications data 123 or are configured to handle telecommunications data 123. For instance, communication devices 101-105 may exchange voice or data packets with a Base Transceiver Station (BTS).

While handling the telecommunications data 123, each communication device 101-105 collects performance data on its own performance in step 202. Performance data comprises any information that indicates the performance of a device, component, system, application, process, etc. Examples of performance data include call completion rate and a number of calls per second. Each communication device 101-105 transfers the performance data 121 to control system 110 (see FIG. 1). Each communication device 101-105 may periodically transfer the performance data 121 to control system 110, such as every thirty seconds, every one minute, every five minutes, etc.

Control system 110 receives the performance data 121 from each of the communication devices 101-105. In step 204, in response to receiving the performance data 121, control system 110 processes the performance data 121 from communication devices 101-105 to generate a performance file that indicates the performance of each of the communication devices. A performance file comprises any record, list, table, or data structure that includes information on performance. The performance file may include a list of some or all of the performance data 121 provided by each of the communication devices 101-105. After generating the performance file, control system 110 transfers the performance file 122 to each of the communication devices 101-105. Control system 110 may periodically transfer the performance file 122 to each of the communication devices 101-105, such as every thirty seconds, every one minute, every five minutes, etc.

Each communication device 101-105 receives the performance file 122. In step 206, responsive to receiving the performance file 122, each communication device 101-105 processes the performance file 122 to compare its performance to the performance of the other peer communication devices 101-105. For instance, responsive to communication device 101 receiving the performance file 122, communication device 101 may process the performance file 122 to compare its performance data with the performance data of its peer communication devices 102-105.

Each of the communication devices 101-105 may also attempt to improve its performance based on the comparison of its performance with the performance of the other peer communication devices 101-105. If communication device 101, for example, attempts to improve its performance in step 206, step 206 may include the steps illustrated in FIG. 2B. In step 208, communication device 101 monitors communication device 101 to detect a fault internal to communication device 101. In monitoring communication device 101, communication device 101 may compare its performance data with the performance data of other peer communication devices 102-105. Responsive to detection of the fault, communication device 101 processes the performance file 122 to identify one or more recovery actions, in step 210. A recovery action comprises any measure or measures used to address a fault condition. Communication device 101 then performs the recovery actions to attempt to cure the fault, in step 212. Communication device 101 determines if the fault has been cured in step 214. If the fault has not been cured, then communication device 101 generates a report of the fault and transfers the report of the fault to control system 110, in step 216. Responsive to receiving the report of the fault, control system 110 may identify one or more recovery actions, and perform the recovery actions on communication device 101 or instruct communication device 101 to perform the recovery actions.

The above-described elements may be comprised of instructions that are stored on storage media. The instructions can be retrieved and executed by processors on communication devices 101-105 and/or control system 110. Some examples of instructions are software, program code, and firmware. Some examples of storage media are memory devices, tape, disks, integrated circuits, and servers. The instructions are operational when executed by the processors to direct the processors to operate in accord with the invention. The term “processor” refers to a single processing device or a group of inter-operational processing devices. Some examples of processors are computers, integrated circuits, and logic circuitry. Those skilled in the art are familiar with instructions, processors, and storage media.

Telecommunication system 100 may include devices other than communication devices 101-105 that provide performance data to control system 110. Similarly, the other devices may transmit performance data to and receive the performance file from control system 110 to monitor their own performance.

Because communication devices 101-105 actively participate in monitoring telecommunication system 100, communication devices 101-105 do not necessarily have to rely on a centralized system monitor, as in the prior art, to monitor telecommunication system 100. Also, because more of the system monitoring is performed locally on communication devices 101-105, the communication devices 101-105 may advantageously avoid taking incorrect recovery actions or delaying the initiation of the recovery actions. This may improve the availability and reliability of telecommunication system 100.

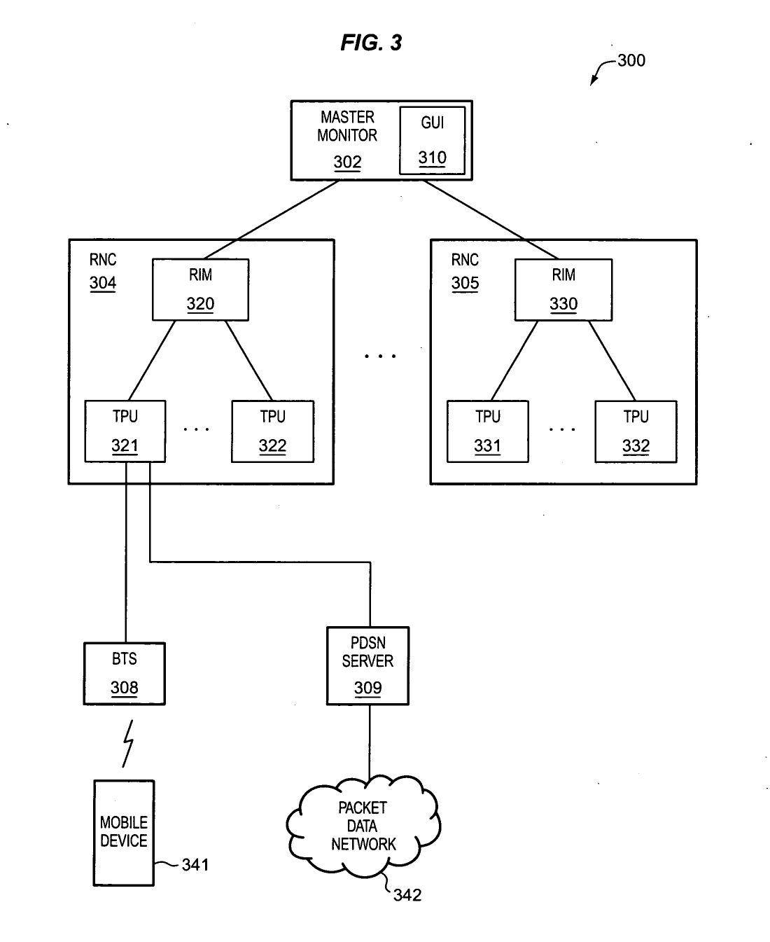

Wireless Communication Network Configuration and Operation—FIGS. 3-5

FIG. 3 illustrates a wireless communication network 300 in an exemplary embodiment of the invention. Wireless communication network 300 includes a master monitor 302, Radio Network Controllers (RNC) 304-305, a Base Transceiver Station (BTS) 308, and a Packet Data Serving Node (PDSN) server 309. Master monitor 302 includes a Graphical User Interface (GUI) 310. RNC 304 includes an RNC Integrity Monitor (RIM) 320 and Traffic Processing Units (TPU) 321-322. RIM 320 may correspond to the control system 110 described in FIG. 1. RNC 305 includes a RIM 330 and TPUs 331-332. Master monitor 302 is coupled to RIM 320 and RIM 330. RIM 320 is coupled to TPUs 321-322. RIM 330 is coupled to TPUs 331-332. TPU 321 is coupled to BTS 308 and PDSN server 309. BTS 308 is able to communicate with a mobile wireless device 341, such as a wireless phone or wireless computer. PDSN server 309 is able to communicate with a packet data network 342. Packet data network 342 may be an Internet Protocol (IP) network, an Asynchronous Transfer Mode (ATM) network, or another packet network. Wireless communication network 300 comprises a CDMA network that provides voice and data services. In other embodiments, wireless communication network 300 may comprise a GSM, TDMA, UMTS, or another network. Wireless communication network 300 may include other components, devices, or systems not shown in FIG. 3. RIMs 320 and 330 may comprise software applications executed by one or more processors (not shown) in RNCs 304-305.

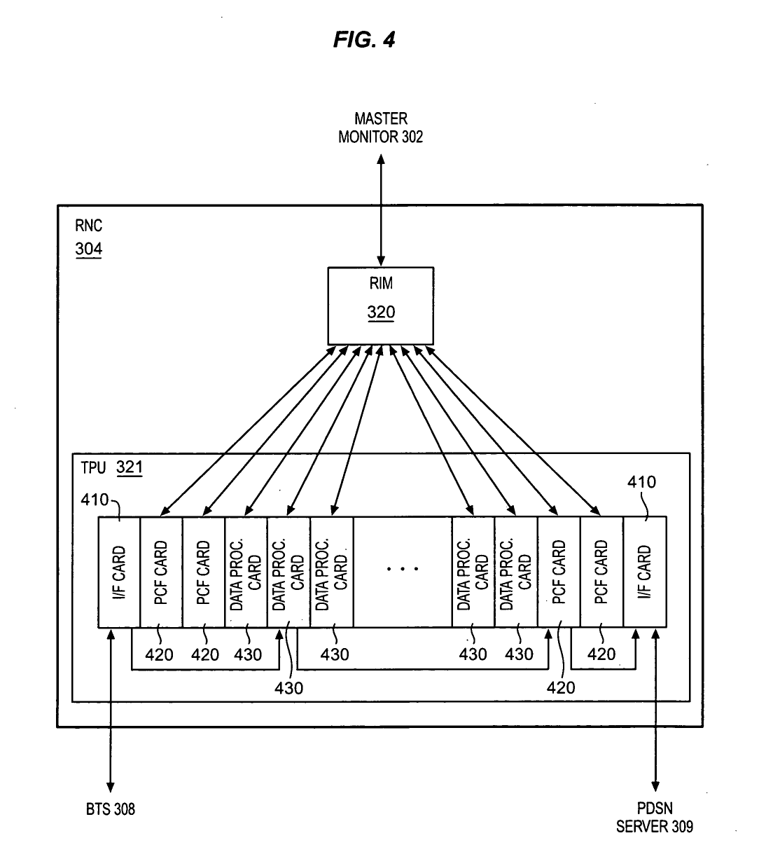

FIG. 4 illustrates RNC 304 in an exemplary embodiment of the invention. FIG. 4 further illustrates the components of TPU 321 within RNC 304. TPU 321 includes interface cards 410, Packet Control Function (PCF) cards 420, and data processing cards 430. Cards 410, 420, and 430 may correspond to the communication devices 101-105 shown in FIG. 1. RNC 304 may include other components, devices, or systems not shown in FIG. 4. Interface cards 410 are configured to connect or interface TPU 321 with devices or systems external to TPU 321, such as BTS 308 or PDSN server 309. PCF cards 420 are configured to interface a Radio Access Network (RAN) and a packet data network 342 (see FIG. 3). To interface a RAN and a packet data network 342, PCF cards 420 establish and maintain a session with a PDSN server 309, where the PDSN server 309 provides access to the packet data network 342. PCF cards 420 may establish the session by identifying an address for the PDSN server 309. Data processing cards 430 are configured to process the actual data traffic (i.e. bearer traffic) for calls.

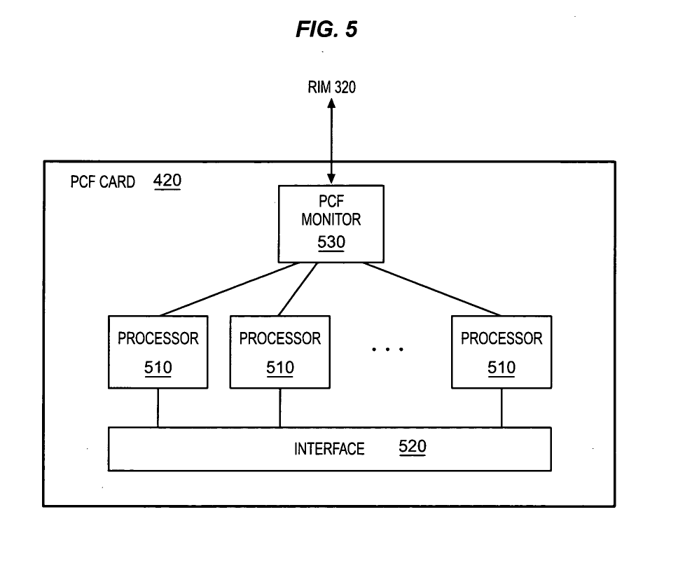

FIG. 5 illustrates a PCF card 420 in an exemplary embodiment of the invention. PCF card 420 includes a plurality of processors 510, an interface 520, and a PCF monitor 530. Processors 510 are each coupled to interface 520 and PCF monitor 530. PCF monitor 530 is configured to communicate with RIM 320 shown in FIGS. 3 and 4. Processors 510 are configured to perform one or more applications on the data traffic. Interface 520 is configured to interface processors 510 with other cards. Interface 520 may be an Ethernet interface or another type of interface. PCF card 420 may include other components, devices, or systems not shown in FIG. 5. Although PCF monitor 530 is illustrated as a separate component, one skilled in the art should understand that the PCF monitor 530 may comprise software applications executed by one or more of the processors 510.

Wireless communication network 300 includes a hierarchy of monitoring that is explained in the following description. In FIG. 5, PCF card 420 actively monitors its own performance with PCF monitor 530. PCF monitor 530 monitors the performance of processors 510, the performance of applications being executed on processors 510, and the performance of other devices or processes in PCF card 420, to collect performance data for PCF card 420. PCF monitor 530 has inside information about PCF card 420, and PCF monitor 530 uses the performance data and the inside information to determine a performance grade for PCF card 420. The performance data for PCF monitor 530 may include a call completion rate, a signaling load level, and a bearer load level for PCF card 420. PCF monitor 530 then periodically forwards the performance data and the performance grade for PCF card 420 to RIM 320.

In FIG. 4, RIM 320 receives performance data and performance grades from each of the PCF cards 420 in TPU 321. Each of the data processing cards 430 in TPU 321 also includes a monitor (not shown) similar to the PCF monitor 530 in the PCF cards 420 (see FIG. 5). Thus, each of the data processing cards 430 forwards performance data and a performance grade to RIM 320. Interface cards 410 may also forward performance data, which is not shown in FIG. 4.

RIM 320 processes the performance data and the performance grades from the cards 420, 430 in TPU 321. Based on the performance data and the performance grades from the cards 420, 430, RIM 320 grades the performance of each card. RIM 320 generates a performance map (i.e., a performance file) that identifies each card, the grades for each card, key performance data for each card, and other information. RIM 320 then periodically forwards the performance map to each card 420, 430 in TPU 321.

In FIG. 5, PCF monitor 530 receives the performance map. PCF monitor 530 can then use the performance map to evaluate the performance of PCF card 420 compared to the performance of other peer cards 420, 430 in TPU 321 (see FIG. 4). If PCF monitor 530 determines that the performance of its PCF card 420 is poor compared to other peer PCF cards 420, then PCF monitor 530 may initiate recovery actions to attempt to improve the performance of its PCF card 420. PCF monitor 530 may run a local, directed audit on PCF card 420 to attempt to detect a problem. PCF monitor 530 may also re-initialize PCF card 420, or trigger a failover or restart of one of the processors 510 in PCF card 420. If PCF monitor 530 is not able to locally provide the proper recover actions, PCF monitor 530 may report the fault to RIM 320 for further action. RIM 320 provides a secondary level of monitoring and recovery in the event that PCF monitor 530 is not able to provide the proper recovery actions.

Advantageously, PCF monitor 530 is given enough information about the performance of other peer cards 420, 430 to make informed decisions about the performance of its PCF card 420 and initiate the appropriate recovery actions. PCF monitor 530 does not have to rely on a higher level system monitor to make the decisions.

In FIG. 4, RIM 320 grades the performance of RNC 304 based on the performance data provided by the individual cards and other information. The grade may be a pass/fail grade. For instance, if RIM 320 determines a “failed” grade for RNC 304, then calls should be routed away from RNC 304. RIM 320 forwards the performance data and a performance grade for RNC 304 to master monitor 302 (see FIG. 3). RIM 330 operates similarly to RIM 320 to forward performance data and a performance grade for RNC 305 to master monitor 302.

Master monitor 302 collects the performance data for the RNCs 304-305 to generate a performance log for wireless communication network 300. Master monitor 302 also provides the performance data for RNCs 304-305 to network personnel through GUI 310 to report the overall status of wireless communication network 300.

If the performance grade of RNC 304 drops, then RIM 320 may raise early alarms to allow network personnel to get an early start at diagnosing and repairing a fault that in the conventional system may have been a silent, latent, or undetected fault. The network personnel may evaluate the performance data of the RNCs 304-305, as provided by master monitor 302, to determine the appropriate recovery action. One example of a recovery action for RIM 320 may be to trigger a failover or a restart of a service.

The following example further illustrates the operation of wireless communication network 300. Assume that mobile wireless device 341, having a previously established call, transmits bearer traffic to BTS 308 (see FIG. 3). BTS 308 transmits the bearer traffic, in the form of packets or cells, to TPU 321. In FIG. 4, interface card 410 receives the bearer traffic. Interface card 410 forwards the bearer traffic to data processing card 430. Data processing card 430 performs one or more applications on the bearer traffic and forwards the bearer traffic to PCF card 420. In FIG. 5, one of the processors 510 receives the bearer traffic through interface 520. The processor 510 maintains an established session with PDSN server 309 (see FIG. 3) and may perform one or more applications on the bearer traffic for forwarding the bearer traffic to PDSN server 309 through interface card 410 (see FIG. 4). For instance, the processor 510 may add an address for PDSN server 309 to the header of the packets containing the bearer traffic in order to route the bearer traffic to PDSN server 309. Responsive to receiving the bearer traffic, PDSN server 309 forwards the bearer traffic over the packet data network 342 (see FIG. 3).

In FIG. 5, further assume that PCF monitor 530 determines that PCF card 420 is operating at a 30% bearer load level. If PCF monitor 530 processes the performance map to determine that other peer cards 420, 430 are operating at 90% or better, then PCF monitor 530 may determine that its PCF card 420 has an internal problem. PCF monitor 530 may then initiate recovery actions on its PCF card 420. If PCF monitor 530 processes the performance map to determine that the data processing card 430, forwarding the bearer traffic to PCF card 420, has a high re-transmission rate, then PCF monitor 530 may determine that there is a problem external to its PCF card 420. PCF monitor 530 may advantageously avoid taking unnecessary recovery actions.

1. A telecommunication system configured to provide distributed system monitoring, the telecommunication system comprising:
a control system; and
a plurality of peer communication devices, each communication device, responsive to handling telecommunications data, collects performance data and transfers the performance data to the control system;
the control system, responsive to receipt of the performance data from the communication devices, processes the performance data from each of the communication devices to generate a performance file that indicates the performance of each of the communication devices, and transfers the performance file to each of the communication devices;
each communication device, responsive to receipt of the performance file, processes the performance file to compare its performance to the performance of the other peer communication devices.

2. The telecommunication system of claim 1 wherein each communication device processes the performance file to attempt to improve its performance.

3. The telecommunication system of claim 1 wherein one of the communication devices monitors the one communication device to detect a fault.

4. The telecommunication system of claim 3 wherein the one communication device, responsive to detection of the fault, processes the performance file to identify at least one recovery action and performs the at least one recovery action.

5. The telecommunications system of claim 4 wherein the one communication device determines if the fault is cured by the at least one recovery action, generates a report of the fault if the fault is not cured by the at least one recovery action, and transfers the report of the fault to the control system.

6. The telecommunications system of claim 5 wherein the control system, responsive to receipt of the report of the fault, identifies at least one recovery action, and performs the at least recovery action on the one communication device.

7. The telecommunication system of claim 1 wherein each communication device processes the performance file by comparing its performance data with performance data of the other peer communication devices.

8. The telecommunications system of claim 1, wherein:
each communication device periodically transfers the performance data to the control system.

9. The telecommunications system of claim 1 wherein the performance data includes a performance grade for each communication device.

10. The telecommunications system of claim 1 wherein the performance file includes a list of performance data for each of the plurality of peer communication devices.

11. A method of operating a telecommunication system to provide distributed system monitoring, wherein the telecommunication system comprises a plurality of peer communication devices coupled to a control system, the method comprising the steps of:
collecting performance data in each of the plurality of peer communication devices responsive to each of the plurality of peer communication devices handling telecommunications data,
transferring the performance data from each of the plurality of peer communication devices to the control system,
processing the performance data from each of the communication devices in the control system to generate a performance file that indicates the performance of each of the communication devices,
transferring the performance file from the control system to each of the communication devices, and
processing the performance file in each of the plurality of peer communication devices to compare its performance to the performance of the other peer communication devices.

12. The method of claim 111 further comprising the step of:
processing the performance file in each of the plurality of peer communication devices to attempt to improve its performance.

13. The method of claim 11 further comprising the step of:
monitoring each of the plurality of peer communication devices to detect a fault.

14. The method of claim 13 further comprising the steps of:
responsive to detecting the fault in one of the plurality of communication devices, processing the performance file in the one communication device to identify at least one recovery action, and
performing the at least one recovery action.

15. The method of claim 14 further comprising the steps of:
determining if the fault is cured by the at least one recovery action,
generating a report of the fault if the fault is not cured by the at least one recovery action, and
transferring the report of the fault to the control system.

16. The method of claim 15 further comprising the steps of:
responsive to receipt of the report of the fault in the control system, identifying at least one recovery action, and performing the at least one recovery action on the one communication device.

17. The method of claim 11 wherein the step of processing the performance file in each of the plurality of peer communication devices to compare its performance to the performance of the other peer communication devices comprises the step of:
processing the performance file by comparing its performance data with performance data of the other peer communication devices.

18. The method of claim 11 wherein the step of transferring the performance data from each of the plurality of peer communication devices to the control system comprises the step of:
periodically transferring the performance data from each of the plurality of peer communication devices to the control system.

19. The method of claim 11 wherein the performance data includes a performance grade for each communication device.

20. The method of claim 11 wherein the performance file includes a list of performance data for each of the plurality of peer communication devices.
